(19) United States
(12) Patent Application Publication
(10) Pub. No.: US 2026/0140058 A1
(43) Pub. Date: May 21, 2026

(54) METHOD FOR MANUFACTURING SILICON CARBIDE SEMICONDUCTOR DEVICE

(71) Applicant: DENSO CORPORATION, Kariya-city (JP)

(72) Inventors: Yuichi TAKEUCHI, Kariya-city (JP); Yusuke HAYAMA, Kariya-city (JP)

(21) Appl. No.: 19/450,487

(22) Filed: Jan. 15, 2026

Related U.S. Application Data
(63) Continuation of application No. PCT/JP2024/025363, filed on Jul. 12, 2024.

(30) Foreign Application Priority Data
Jul. 24, 2023 (JP) 2023-120241

(51) Int. Cl. G01N 21/64; C30B 25/20; C30B 29/36; H10P 74/20

(52) U.S. Cl. CPC G01N 21/6489; C30B 25/20; C30B 29/36; H10P 74/203

(57) ABSTRACT

In a method for manufacturing a silicon carbide semiconductor device, an n-type silicon carbide doped with an n-type impurity, which is to be used for forming an n-type silicon carbide substrate, is prepared. An emission spectrum intensity due to a level formed in a vicinity of a mid-gap of silicon carbide by a p-type impurity mixed in the n-type silicon carbide is measured by an emission spectrum measurement based on excitation. A quality determination to determine whether or not the n-type silicon carbide is a standard article is performed by comparing the emission spectrum intensity with a reference value set based on an emission spectrum intensity corresponding to the mid-gap.

### CROSS REFERENCE TO RELATED APPLICATIONS

The present application is a continuation application of International Patent Application No. PCT/JP2024/025363 filed on Jul. 12, 2024, which designated the U.S. and claims the benefit of priority from Japanese Patent Application No. 2023-120241 filed on Jul. 24, 2023. The entire disclosures of all of the above applications are incorporated herein by reference.

### TECHNICAL FIELD

The present disclosure relates to a method for manufacturing a silicon carbide (SiC) semiconductor device, which manages a SiC ingot, a SiC substrate or the like used for manufacturing the SiC semiconductor device, and extracts one suitable for manufacturing the SiC semiconductor device with desired characteristics.

### BACKGROUND

For example, there has been known a method for evaluating the dislocation density of a SiC substrate using a photoluminescence (PL) method, which is a non-destructive inspection method.

### SUMMARY

According to an aspect of the present disclosure, a method for manufacturing a silicon carbide semiconductor device, includes: preparing an n-type silicon carbide doped with an n-type impurity, which is to be used for forming an n-type silicon carbide substrate; measuring an emission spectrum intensity due to a level formed in a vicinity of a mid-gap of silicon carbide by a p-type impurity mixed in the n-type silicon carbide by an emission spectrum measurement based on excitation; and performing a quality determination to determine whether or not the n-type silicon carbide is a standard article by comparing the emission spectrum intensity with a reference value set based on an emission spectrum intensity corresponding to the mid-gap.

### BRIEF DESCRIPTION OF DRAWINGS

Features and advantages of the present disclosure will become more apparent from the following detailed description made with reference to the accompanying drawings, in which:

FIG. 1 is a diagram showing a manufacturing process of an n-type SiC substrate made of SiC according to a first embodiment;

FIG. 2 is a graph showing a change in PL spectrum intensity with respect to a wavelength of a PL light;

FIG. 3 is a graph showing a relationship between an p-type impurity concentration and a PL spectrum intensity at a wavelength of around 520 nm;

FIG. 4 is a flowchart showing a wafer-process feasibility inspection process;

FIG. 5 is a diagram showing a schematic configuration of an inspection device;

FIG. 6 is a flowchart showing a shipping inspection process; and

FIG. 7 is a flowchart showing a wafer incoming inspection process.

### DETAILED DESCRIPTION

In an n-type SiC substrate doped with an n-type impurity, such as nitrogen (N) element, at a high concentration, if the amount of p-type impurity element other than the n-type impurity contained therein increases, the amount of warpage of the SiC substrate after ion implantation is likely to increase. On the other hand, the p-type impurity in the SiC substrate improves the diode current degradation characteristics of an element formed on the SiC substrate. For this reason, it is important to establish a method for managing the p-type impurity concentration in the n-type SiC. By accurately managing the p-type impurity concentration, it is possible to control the amount of warpage of the SiC substrate while improving the diode current degradation characteristics. As a result, it is possible to manufacture highly reliable SiC semiconductor devices.

A method for evaluating the dislocation density of a SiC substrate by a non-destructive inspection method has been proposed. However, there is no technique for evaluating and managing the p-type impurity concentration by the non-destructive inspection method. The p-type impurity concentration has been measured by a destructive inspection, such as a secondary ion mass spectrometry (SIMS), which is time-consuming and costly in the manufacture of SiC wafers, which are used to manufacture SiC substrates. Furthermore, in the destructive inspection, the number of materials to be inspected is likely to be small. For example, it is difficult to perform 100% inspection, that is, to inspect all the materials. This makes difficult to manufacture highly reliable SiC semiconductor devices.

The present disclosure provides a method for manufacturing a SiC semiconductor device, which is capable of producing a highly reliable SiC semiconductor device, by managing a p-type impurity concentration in a SiC ingot, SiC wafer or the like made of n-type SiC.

According to an aspect of the present disclosure, a method for manufacturing a silicon carbide semiconductor device, includes: preparing an n-type silicon carbide doped with an n-type impurity, which is to be used for forming an n-type silicon carbide substrate; measuring an emission spectrum intensity due to a level formed in a vicinity of a mid-gap of silicon carbide by a p-type impurity mixed in the n-type silicon carbide by an emission spectrum measurement based on excitation; and performing a quality determination to determine whether or not the n-type silicon carbide is a standard article by comparing the emission spectrum intensity with a reference value set based on an emission spectrum intensity corresponding to the mid-gap.

In the measuring of the emission spectrum intensity, the emission spectrum measurement may be performed based on the excitation that is caused by irradiating a photoluminescence light onto the n-type silicon carbide, and an emission spectrum intensity corresponding to a p-type impurity concentration may be measured by measuring an emission spectrum intensity of the photoluminescence light of a wavelength of 520 nm.

In this way, the emission spectrum intensity under excitation of the n-type SiC, such as a SiC ingot or a SiC wafer, used to form the n-type SiC substrate is compared with the reference value. As a result, it is possible to manage the p-type impurity concentration in the SiC by the non-destructive inspection. Furthermore, since the p-type impurity concentration can be managed by the non-destructive inspection, the number of materials to be inspected can be increased, as compared with the destructive inspection. For example, it becomes possible to undergo 100% inspection. As a result, it is possible to manufacture highly reliable SiC semiconductor devices.

Hereinafter, embodiments and examples of the present disclosure will be described with reference to the drawings. In the following descriptions, the same or equivalent components will be described with the same reference numerals throughout the embodiments including other embodiments and the examples.

### First Embodiment

A method for manufacturing a SiC semiconductor device according to a first embodiment will be described. The SiC semiconductor device is manufactured, for example, in the following order.

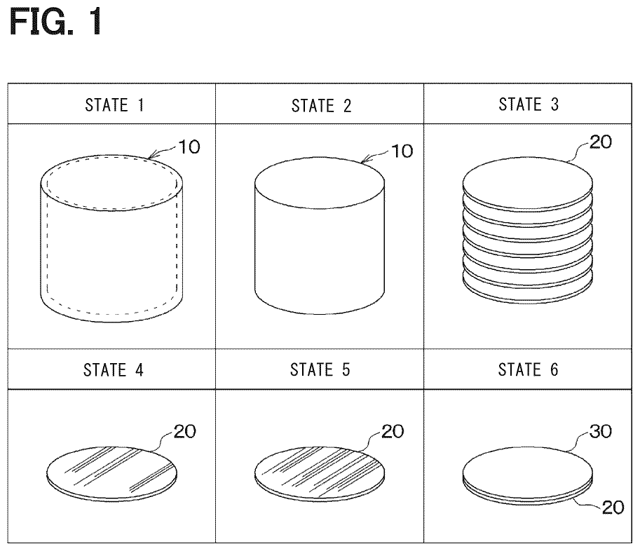

First, as shown in State 1 of FIG. 1, a SiC ingot 10 made of a SiC single crystal is grown in a growth crucible by a sublimation method or a gas growth method. In this case, the SiC ingot 10 for forming an n-type SiC substrate, in which the SiC is highly doped with the n-type impurity, can be obtained by introducing an n-type impurity, such as nitrogen (N), in addition to a SiC raw material. Next, the grown SiC ingot 10 is removed from the growth crucible, and an unnecessary part, such as a part shown outside a dashed line in State 1 of FIG. 1, is cut off. As a result, a cylindrical SiC ingot 10, as shown in State 2 of FIG. 1, is obtained. Then, the SiC ingot 10 is sliced with a slicer into wafers, and the sliced wafers are subjected to a grinding process. Thus, as shown in State 3 of FIG. 1, SiC wafers 20 for forming n-type SiC substrates are produced. Next, the SiC wafer 20 is subjected to a lapping process. Thus, as shown in State 4 of FIG. 1, the SiC wafer 20 having polished surfaces is produced. Then, the SiC wafer 20 is subjected to a chemical mechanical polishing (CMP) process, so the SiC wafer 20 having polished surfaces with a higher degree of flatness than that after the lapping process is produced, as shown in State 5 of FIG. 1. In a case where the SiC wafer 20 is used to form an element such as a MOSFET, an epitaxial film 30 is formed on the surface of the SiC wafer 20, as shown in State 6 of FIG. 1, and various semiconductor processes such as ion implantation are performed, thereby to form the element. For example, an n-channel vertical MOSFET is formed as the element. Thereafter, the SiC wafer 20 is diced into chips. As a result, a SiC semiconductor device having the n-type SiC substrate divided as a unit of chip from the SiC wafer 20 and formed with the element is produced.

At any stage in the manufacturing process of this SiC semiconductor device, the p-type impurity concentration is measured by a non-destructive inspection. As a result of the non-destructive inspection, a material that does not meet a desired standard is excluded from the manufacturing process of the SiC semiconductor device, and only the materials that meet the desired standard are used in the manufacturing process of the SiC semiconductor device.

Here, in an n-type SiC substrate in which SiC is highly doped with the n-type impurity, such as N, if the amount of p-type impurity elements other than the n-type impurity increases, the amount of warpage of the SiC substrate after ion implantation is likely to increase. Examples of the p-type impurity include aluminum (Al), boron (B), titanium (Ti), and vanadium (V). On the other hand, it has been confirmed that the p-type impurity concentration in the n-type SiC substrate improves the diode current degradation characteristics of the element formed in the SiC substrate. In other words, even if a current is passed through a built-in diode in a forward direction, an increase in the on-resistance can be suppressed. For this reason, it is important to establish a method for managing the p-type impurity concentration in an n-type SiC substrate. By managing the p-type impurity concentration with high accuracy, it becomes possible to manufacture highly reliable SiC semiconductor devices.

However, if the p-type impurity concentration is evaluated and managed by the destructive inspection, the number of materials to be inspected is reduced. For example, it is difficult to perform 100% inspection. In such a case, it becomes difficult to manufacture highly reliable SiC semiconductor devices.

Therefore, the inventors of the present disclosure have studied to evaluate and manage the p-type impurity concentration through a non-destructive inspection using a photoluminescence (PL) method.

Conventionally, there is a technique for evaluating the dislocation density in a SiC substrate by the non-destructive inspection using the PL method. However, the PL method has not been used to evaluate or manage the p-type impurity concentration.

This is because the PL spectrum intensity under excitation when a PL light is irradiated onto the SiC substrate is composed of a superposition of an emission intensity originating from the levels due to dopants in the SiC substrate and an emission intensity dependent on the amount of the dopants. That is, the evaluation using the PL method, in other words, a PL spectrum evaluation cannot accurately separate and evaluate the quantity of dopants for individual elements.

However, hole absorption, which affects the degradation of a built-in diode of an element formed in a SiC semiconductor device, is strongly dependent on the levels in the vicinity of a mid-gap in a SiC transition band. Therefore, the amount of the levels formed by the p-type impurities in the vicinity of the mid-gap of SiC can be evaluated by the PL spectrum. By using this principle, it becomes possible to evaluate and manage the concentration of the p-type impurities present in the n-type SiC substrate.

In this case, the built-in diode refers to a diode formed by a PN junction in the element formed in the SiC semiconductor device. For example, when an n-type MOSFET is formed as the element, the built-in diode is formed at the PN junction between an n-type drift layer and a p-type base layer. The mid-gap refers to the energy at the center between the minimum energy of a conduction band and the maximum energy of a valence band, which form the energy gap. The composition ratio of p-type impurity elements in the SiC ingot 10 or the SiC wafer 20 is proportional to the composition ratio of the SiC raw materials used for crystal growth. In the case of the sublimation method, the p-type impurities are contained depending on the degree of purification of the Si raw material powder and the C raw material powder, which are used as the SiC raw materials, and the composition ratio of the SiC raw materials is thus determined by the contents of the p-type impurities. Regarding the SiC raw material composition ratio, the SiC raw materials to be used are determined to some extent by each substrate manufacturer, and therefore the composition ratio of p-type impurity elements in the SiC ingot 10 or the SiC wafer 20 tends to be similar in each substrate manufacturer. Of course, even in the same substrate manufacturer, if the composition ratio of the SiC raw materials used in crystal growth changes, the composition ratio of the p-type impurity elements in the SiC ingot 10 or the SiC wafer 20 also changes.

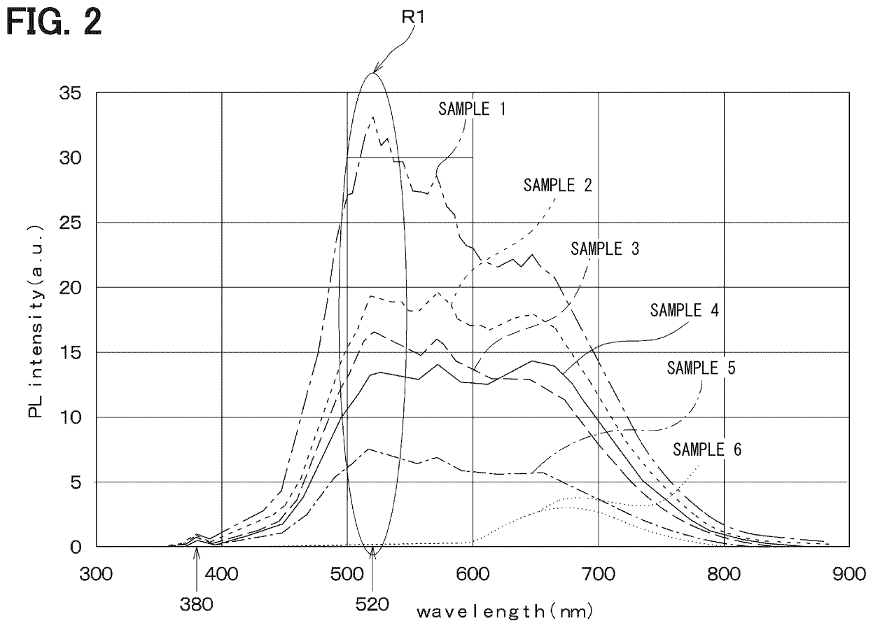

Specifically, multiple SiC wafers 20 manufactured by multiple substrate manufacturers were prepared. The PL light having a wavelength energy of 350 nm was irradiated onto the multiple SiC wafers 20, and the change in a PL spectrum intensity ratio with respect to the wavelength of the PL light was evaluated for the multiple SiC wafers 20. FIG. 2 shows the results.

The PL spectrum intensity is affected by a change in intensity of the PL light source and the like, and may be indicated as different values even if the p-type impurity concentration is the same. On the other hand, the PL spectrum intensity has a peak in a wavelength range of 380±5 nm, which corresponds to the band gap energy of SiC. It has been confirmed that this peak intensity is the same regardless of the p-type impurity concentration if there is no change in the intensity of the PL light source. Therefore, the PL spectrum intensity ratio is obtained by normalizing the PL spectrum intensity at each wavelength using the peak intensity of the PL spectrum in the wavelength range of 380±5 nm as a reference. In other words, the PL spectrum of each SiC wafer 20 is adjusted so that the peak intensity generated in the wavelength range of 380±5 nm has the same height, and the heights of the PL spectrum intensity in the other wavelength ranges are adjusted by multiplying the adjustment rate of the height. The values after this adjustment constitute the PL spectrum intensity ratio based on the peak intensity of the PL spectrum generated in the wavelength range of 380±5 nm.

By using such a PL spectrum intensity ratio, even if there is a change in the intensity of the PL light source, it can be canceled out. The peak of the PL spectrum intensity ratio occurs at the wavelength of approximately 380 nm, but the wavelength may vary slightly. For this reason, the peak of the PL spectrum intensity ratio present in the frequency band of 380±5 nm is used as the reference.

As shown in FIG. 2, six SiC wafers 20 were prepared as samples 1 to 6. The change in PL spectrum intensities with respect to the wavelength of the PL light was examined for the six SiC wafers 20. As a result, it was found that the PL spectrum intensities of the SiC wafers 20 have different characteristics. When the PL light with the energy of 350 nm is irradiated, the wavelength that is thought to have a particular effect on the current degradation characteristics of the built-in diode is about 520 nm. When the PL light with the energy of 350 nm is incident, a reflected light of the same wavelength of 350 nm will be returned as long as there are no p-type impurities or the like. However, if there are the levels based on the p-type impurities, the PL light will be absorbed, and the energy will be converted, resulting in the shift of the wavelength. As a result, a reflected light of a wavelength of about 520 nm, which has lower energy, is returned, and the PL spectrum intensity ratio has a peak in a wavelength band of about 520 nm, as shown in a region R1 in FIG. 2.

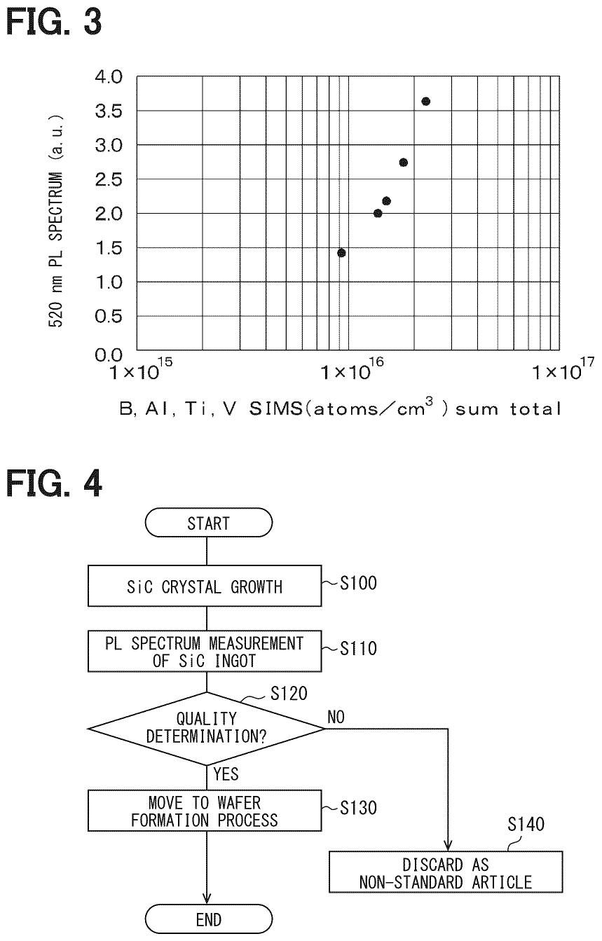

For the samples 1 to 5, the total p-type impurity concentration of Al, B, Ti, and V was measured by the destructive inspection using the SIMS analysis, and the relationship between the measurement result and the PL spectrum intensity at the wavelength of around 520 nm was examined. FIG. 3 shows the obtained results.

As shown in FIG. 3, it is apparent that there is a correlation between the p-type impurity concentration and the PL spectrum intensity at the wavelength of around 520 nm. Therefore, by comparing the PL spectrum intensity ratio when the PL light is irradiated with the reference value of the PL spectrum corresponding to the mid-gap, it is possible to determine whether or not the SiC substrate has the desired p-type impurity concentration. For example, the PL spectrum intensity ratio at the wavelength of around 520 nm after normalization increases as the p-type impurity concentration increases. Therefore, when the PL spectrum intensity ratio is within a range of the reference value, it can be determined that the material is suitable for manufacturing a highly reliable SiC semiconductor device. On the other hand, when the PL spectrum intensity ratio is not within the range of the reference value, it can be determined that the material is not suitable for manufacturing a highly reliable SiC semiconductor device.

In this case, the reference value is set based on the specifications of the required SiC semiconductor device. As described above, the amount of the warpage of the substrate increases with the increase in the p-type impurity concentration. However, the presence of the p-type impurity improves the diode current degradation characteristics. For this reason, for example, a lower limit threshold that satisfies the diode conduction degradation characteristics and an upper limit threshold that satisfies the amount of warpage of the SiC substrate being equal to or less than an allowable value are set, and a range from the lower limit threshold to the upper limit threshold is set as the reference value. When the PL spectrum intensity ratio is at the reference value, the article subjected to the measurement of the PL spectrum intensity ratio is determined as a standard article. In a case where the diode current degradation characteristics are not considered as an important item, the upper limit threshold described above can be used as the reference value. In this case, if the PL spectrum intensity ratio is equal to or less than the reference value, the article can be determined as the standard article that can keep the amount of warpage of the SiC substrate to be equal to or less than the allowable value.

In this way, the PL spectrum intensity ratio when the n-type SiC used to form the n-type SiC substrate, specifically, the SiC ingot 10 or the SiC wafer 20, is irradiated with the PL light is compared with the reference value. As a result, it is possible to manage the p-type impurity concentration in SiC by the non-destructive inspection. Since the p-type impurity concentration can be managed by the non-destructive inspection, the number of articles to be inspected can be increased, as compared to the case of the destructive inspection. For example, it is possible to perform 100% inspection. As such, it is possible to manufacture highly reliable SiC semiconductor devices.

The PL spectrum measurement can be performed at a temperature of 21 to 27 degrees Celsius (° C.) , which is considered as a normal temperature, in a clean room used in the semiconductor manufacturing. It has been confirmed that, when the PL spectrum is evaluated at a low temperature, it is possible to separate and evaluate the levels dependent on the dopant elements. However, it is necessary to keep an inspection device 40, including the object to be measured, at the low temperature. In this case, the measurement time becomes longer and additional equipment for keeping the temperature low is required. On the other hand, in the case of the evaluation under the normal temperature, although it is not possible to separate and evaluate the levels dependent on the dopant elements, it is possible to easily evaluate the quantity of levels in the vicinity of the mid-gap caused by the p-type impurities, which strongly affect the diode current degradation characteristics. On the other hand, if the temperature is higher than the room temperature, the PL spectrum will broaden, making evaluation difficult. For this reason, it is preferable to perform the evaluation under the normal temperature. The evaluation under the normal temperature enables the p-type impurity concentration to be managed in a shorter time and with simpler equipment than those in the case of the evaluation under the low temperature.

Next, examples for managing the p-type impurity concentration in the SiC ingot 10 or the SiC wafer 20 will be described.

### Example 1

A wafer-process feasibility inspection process for managing the p-type impurity concentration of a SiC ingot 10 before being processed into wafers will be described with reference to a flowchart shown in FIG. 4. FIG. 4 shows the wafer-process feasibility inspection process.

First, in S100, an n-type SiC ingot 10 is prepared by crystal-growing an n-type SiC single crystal. For example, a sublimation crystal growth apparatus (not shown) is prepared, and powders of SiC raw materials are placed in a growth crucible provided in the sublimation crystal growth apparatus. Next, the SiC raw materials are heated and sublimated by induction heating or the like, and N as the n-type impurity is introduced. As a result, the n-type SiC single crystal is grown on the surface of a seed crystal (not shown) placed in the growth crucible, thereby to produce the SiC ingot 10, as shown in State 1 of FIG. 1. The grown SiC ingot 10 is then removed from the graphite crucible, and an unnecessary part is cut off. As a result, a cylindrical SiC ingot 10, as shown in State 2 of FIG. 1, is obtained.

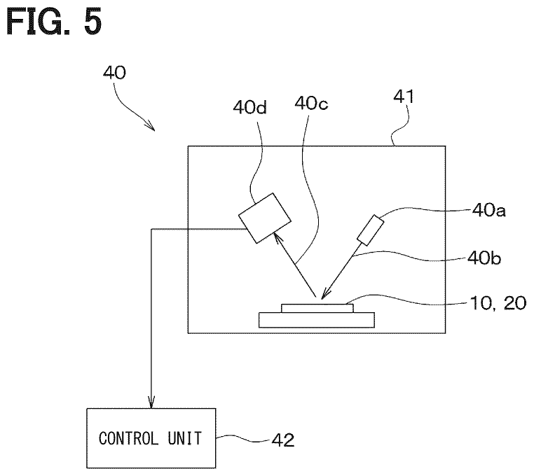

Then, the processes of S110 and after are performed. The processes of S110 and after are performed by an inspection device 40 shown in FIG. 5. The inspection device 40 has a PL inspection unit 41 and a control unit 42. The PL inspection unit 41 has a PL light source 40a that applies a PL light 40b to an object to be inspected and a light receiving unit 40d that receives a reflected light 40c, thereby to measure a PL spectrum intensity. The control unit 42 receives the inspection results from the PL inspection unit 41 and performs various calculations.

In S110, the PL inspection unit 41 measures the PL spectrum of the SiC ingot 10, and the control unit 42 stores the measurement results therein. For example, the PL spectrum intensity can be measured by irradiating the PL light having the energy of wavelength of 350 nm onto both end faces and side faces of the cylindrical SiC ingot 10 with respect to a central axis of the cylindrical SiC ingot 10.

Then, in S120, the control unit 42 normalizes the PL spectrum intensities measured in S110 to the PL spectrum intensity ratio, and performs a quality determination that determines whether the p-type impurity concentration is acceptable or not based on the PL spectrum intensity ratio in the vicinity of the wavelength of 520 nm after the normalization.

For example, the peak of the PL spectrum intensity ratio occurring in the wavelength range of 380±5 nm is normalized in advance in an experiment or the like. Also, the reference value for the quality determination is set in advance through experiments or the like. For example, as described above, the lower limit threshold and the upper limit threshold are set in advance. Furthermore, the height of the peak in the wavelength range of 380±5 nm in the PL spectrum intensity measured in S110 is adjusted to the normalized peak intensity, thereby adjusting the PL spectrum intensity ratio at the other wavelengths. Then, the adjusted PL spectrum intensity ratio in the vicinity of the wavelength of 520 nm is compared with the reference value. As a result, when the PL spectrum intensity ratio is in the range from the lower limit threshold to the upper limit threshold, which is set as the reference value, an affirmative determination is made, in other words, the SiC ingot 10 is determined to be the standard article. Then, the process proceeds to S130. On the other hand, when the PL spectrum intensity ratio is not in the range from the lower limit threshold to the upper limit threshold, the process proceeds to S140.

When the affirmative determination is made in S120, the SiC ingot 10 subjected to the measurement is the standard article. In this case, the process proceeds to S130 in which the SiC ingot 10 subjected to the measurement is allowed to proceed to a wafer formation process to be processed into a wafer. Then, the wafer-process feasibility inspection process is ended. When the negative determination is made in S110, the SiC ingot 10 subjected to the measurement is a non-standard article. Thus, in S140, the SiC ingot 10 subjected to the measurement is discarded as the non-standard article. That is, since the SiC ingot 10 subjected to the measurement is discarded, it is possible to restrict the SiC ingot 10 as the non-standard article from being transferred to the subsequent wafer formation process.

In this way, only the SiC ingot 10 as the standard article is transferred to the wafer formation process for producing the SiC wafers 20, so that the SiC wafers 20 are produced only from the SiC ingot 10 as the standard article. As such, it is possible to obtain the SiC wafers 20 as standard articles. Since the SiC semiconductor devices can be manufactured by using the SiC wafer 20 as the standard article, it is possible to improve the reliability of produced SiC semiconductor devices. Furthermore, since the non-standard article can be eliminated in the stage of the SiC ingot 10 in this manner, it is possible to reduce the manufacturing costs.

### Example 2

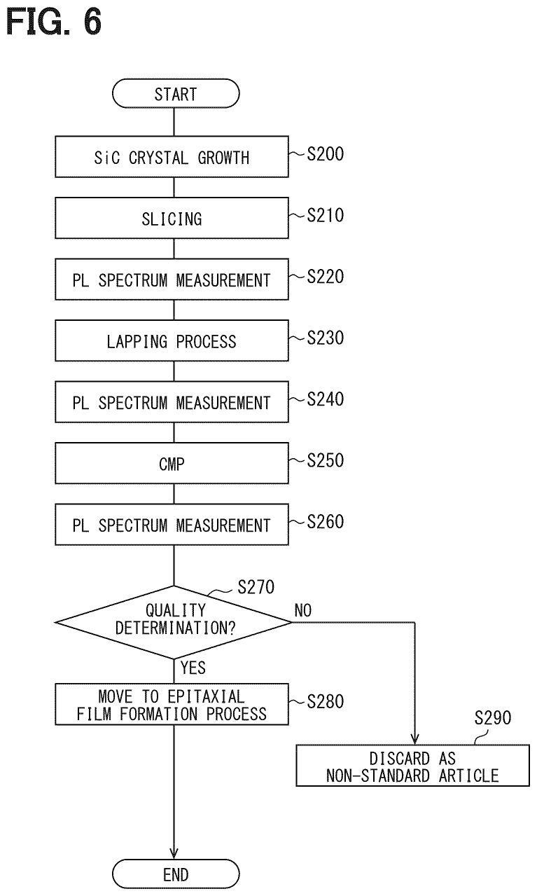

A shipping inspection process for managing the p-type impurity concentration of the SiC wafer 20 during the wafer formation process for producing the n-type SiC wafers 20 will be described with reference to a flowchart shown in FIG. 6. FIG. 6 shows the shipping inspection process.

First, in S200, SiC single crystal is grown, and an unnecessary part is cut off from the grown SiC single crystal. As a result, a cylindrical n-type SiC ingot 10 is produced. This process is performed in the similar manner to the process in S100 of FIG. 4. Subsequently, in S210, the SiC ingot 10 is sliced into wafers with a desired thickness and the surfaces of the sliced wafers are ground. As a result, the n-type SiC wafers 20 as shown in State 3 of FIG. 1 are prepared.

Then, the process proceeds to S220. In S220, the PL spectrum measurement is performed onto the sliced SiC wafer 20. The PL spectrum measurement may be performed onto either the front surface or the back surface of the SiC wafer 20. In this case, the PL spectrum measurement is performed in a similar manner to that in S110 of FIG. 4. The PL inspection unit 41 measures the PL spectrum of the SiC wafer 20, and the control unit 42 stores the measurement results therein.

Next, the process proceeds to S230. In S230, the SiC wafer 20 is subjected to a lapping process. As a result, the SiC wafer 20 the surfaces of which are polished is produced, as shown in State 4 of FIG. 1. Then, the process proceeds to S240. In S240, the PL spectrum measurement is performed onto the lapped SiC wafer 20. Also in this case, the PL spectrum measurement may be performed onto either the front surface or the back surface of the SiC wafer 20. The PL spectrum measurement in S240 is performed in the similar manner to that in S220.

Next, the process proceeds to S250. In S250, the SiC wafer 20 is subjected to the CMP process. As a result, as shown in State 5 in FIG. 1, it is possible to obtain the SiC wafer 20 with the surface polished to a higher degree of flatness than that obtained by the lapping process. Then, the process proceeds to S260. In S260, the PL spectrum measurement is performed onto the SiC wafer 20 after the CMP process. Also in this case, the PL spectrum measurement may be performed onto either the front surface or the back surface of the SiC wafer 20. In this case, the PL spectrum measurement is performed in the similar manner to that in S220.

Thereafter, the process proceeds to S270. In S270, the control unit 42 normalizes the PL spectrum intensity ratios measured in 220, S240, and S260, and performs the quality determination of determining whether or not the p-type impurity concentration is acceptable based on the normalized PL spectrum intensity ratios in the vicinity of the wavelength of 520 nm. In this case, the normalization and the quality determination are performed in similar manners to those in S120 of FIG. 4. Although the PL spectrum intensity ratios are obtained three times, i.e., in S220, S240, and S260, the quality determination may be performed based on only one of them, or may be based on two or more of them. In a case where the quality determination is performed based on the PL spectrum intensity ratios obtained two or more times, if any one of them does not meet the standard of the standard article, the negative determination may be made as the result of the quality determination. Alternatively, if some of them do not meet the standard of the standard article, the negative determination may be made as the result of the quality determination.

When the affirmative determination is made in S270, the process proceeds to S280. When the negative determination is made in S270, the process proceeds to S290. When the affirmative determination is made in S270, the SiC wafer 20 subjected to the measurement is the standard article. Therefore, in S280, the SiC wafer 20 is allowed to proceed to an epitaxial film formation process that is performed before an element formation process for forming the element. In this way, the shipping inspection process for the wafer formation process is ended. When the negative determination is made in S270, the SiC wafer 20 subjected to the measurement is the non-standard article. Therefore, in S290, the SiC wafer 20 subjected to the measurement is discarded as the non-standard article. That is, since the SiC wafer 20 subjected to the measurement is discarded, it is possible to restrict the SiC wafer 20, which is the non-standard article, from being transferred to the subsequent epitaxial film formation process.

Therefore, only the SiC wafers 20 as the standard articles are transferred to the epitaxial film formation process, and the epitaxial film 30 is formed only on the SiC wafers 20 as the standard article. As such, it is possible to obtain the epitaxial wafer as the standard article, and the SiC semiconductor devices can be manufactured by using the epitaxial wafer as the standard article. Accordingly, it is possible to produce highly reliable SiC semiconductor devices. Furthermore, since the non-standard article can be eliminated in the stage of the SiC wafer 20, the evaluation of the p-type impurity concentration can be performed for every single SiC wafer 20, and it is possible to restrict a degraded wafer, which is locally generated, from being released.

### Example 3

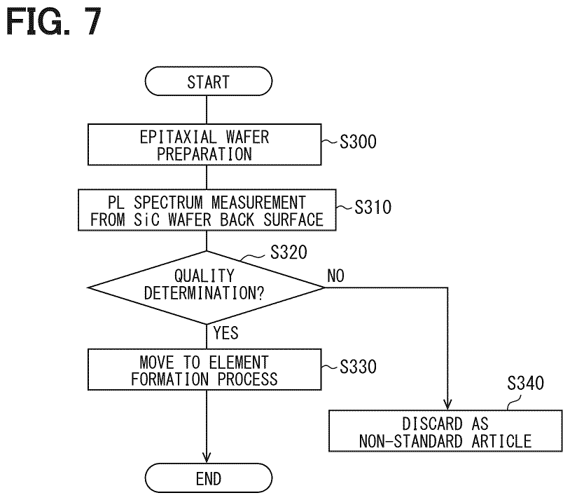

A wafer incoming inspection process for managing the p-type impurity concentration of an epitaxial wafer in which an epitaxial film 30 has been formed on an n-type SiC wafer 20, before an element formation process, will be described with reference to a flowchart of FIG. 7. FIG. 7 shows the wafer incoming inspection process.

First, a cylindrical SiC ingot 10 is sliced into wafers and the wafers are ground to obtain SiC wafers 20. Then, the surfaces of the SiC wafers 20 are polished by a lapping process or a CMP process. Then, in S300 of FIG. 7, an epitaxial wafer is prepared. Specifically, an epitaxial film 30 of SiC is grown on a surface of the SiC wafer 20 after the surface of which has been polished by using a chemical vapor deposition (CVD) or the like. Thus, the epitaxial wafer is produced. Thereafter, the process proceeds to S310. In S310, the PL spectrum of the SiC wafer 20 in the epitaxial wafer is measured. That is, since the epitaxial film 30 is formed on the surface of the SiC wafer 20 on one side, the PL spectrum measurement is performed onto the other surface of the SiC wafer 20 on the other side on which the epitaxial film 30 is not formed, i.e., on a back surface side of the SiC wafer 20. The PL spectrum measurement in this time is performed in the similar manner to that in S110 of FIG. 4. The PL inspection unit 41 measures the PL spectrum of the SiC wafer 20, and the control unit 42 stores the measurement results therein.

Next, the process proceeds to S320. The control unit 42 normalizes the PL spectrum intensity ratios measured in S310, and performs the quality determination of determining whether or not the p-type impurity concentration is acceptable based on the normalized PL spectrum intensity ratios in the vicinity of the wavelength of 520 nm. The normalization and the quality determination in this time are performed in similar manners to those in S120 of FIG. 4.

When the affirmative determination is made in S320, the process proceeds to S330. When the negative determination is made in S320, the process proceeds to S340. When the affirmative determination is made in S320, since the SiC wafer 20 subjected to the measurement is the standard article, this SiC wafer 20 is allowed to transfer to the subsequent element formation process in S330, and the wafer incoming inspection process is then ended. When the negative determination is made in S320, the SiC wafer 20 subjected to the measurement is the non-standard article. Therefore, in S340, the SiC wafer 20 subjected to the measurement is discarded as the non-standard article. That is, the SiC wafer 20 subjected to the measurement is discarded, so that the SiC wafer 20 as the non-standard article is not transferred to the subsequent element formation process.

Therefore, only the SiC wafer 20 as the standard article is transferred to the element formation process, so the elements are formed only on the epitaxial wafer of the SiC wafer 20 which has been determined as the standard article. As such, it is possible to produce highly reliable SiC semiconductor devices. Furthermore, since the non-standard article can be eliminated even in the epitaxial wafer stage, the evaluation of the p-type impurity concentration can be performed for every single SiC wafer 20 and it is possible to restrict a degraded wafer, which is locally generated, from being released.

### Other Embodiments

While the present disclosure has been described in accordance with the embodiments and examples described above, the present disclosure is not limited to the embodiment and examples and includes various modifications and equivalent modifications. In addition, various combinations and configurations, as well as other combinations and configurations that include only one element, more, or less, are within the scope and spirit of the present disclosure.

For example, in the Examples 1 to 3 described above, the PL spectrum measurement for determining the standard or non-standard article is performed in the wafer-process feasibility inspection process, the shipping inspection process, or the wafer incoming inspection process. By performing at least one of these processes, it is possible to determine whether the article is the standard article or the non-standard article by the non-destructive inspection. As such, it is possible to manufacture highly reliable SiC semiconductor devices. Of course, the more PL spectrum measurements are performed, the more accurately the non-standard articles can be eliminated. Therefore, if the PL spectrum measurement is performed in two or all of these processes, it is possible to manufacture further reliable SiC semiconductor devices.

In the Example 2 described above, the PL spectrum measurement is performed in each of timings, after the slicing, after the lapping process, and after the CMP. However, the PL spectrum measurement may be performed in at least one of these timings. Also in such a case, the more the PL spectrum measurements are performed, the more accurately the non-standard articles can be eliminated. Therefore, if the PL spectrum measurements are performed in two or all of these timings, it becomes possible to manufacture SiC semiconductor devices with further higher reliability.

In the embodiment described above, the p-type impurity concentration is managed by the non-destructive inspection using the PL spectrum measurement with the PL light. The p-type impurity concentration can be managed by an emission spectrum measurement based on excitation. For example, the p-type impurity concentration can be managed by a non-destructive inspection by cathodoluminescence (CL) spectrum measurement upon electron irradiation, instead of the PL light irradiation. When an accelerated electron beam of a predetermined wavelength is applied onto a sample, electrons lose energy due to inelastic scattering, but a portion of the energy is used to excite the electrons in the valence band into the conduction band, generating electron-hole pairs. The electrons and the holes then recombine within the sample, emitting CL light. Since the CL spectrum intensity ratio also correlates with the p-type impurity concentration, the p-type impurity concentration can be managed based on the CL spectrum intensity ratio.

However, in the PL spectrum measurement using the PL light, since the electron beam is used, the inspection device 40 can be configured more simply.

In addition, as the management of the p-type impurity concentration based on the PL spectrum intensity ratio, the case that uses the PL spectrum intensity ratio has been exemplified. Although the use of the PL spectrum intensity ratio enables more accurate management of the p-type impurity concentration, the p-type impurity concentration may also be managed based on the PL spectrum intensity itself.

The control unit and the method thereof described in the present disclosure may be realized by a dedicated computer provided by configuring a processor and a memory programmed to execute one or more functions embodied by a computer program. Alternatively, the control unit and the method which are described in the present disclosure may be realized by a dedicated computer provided by configuring a processor to include one or more dedicated hardware logic circuits. Alternatively, the control unit and the method described in the present disclosure may be implemented by one or more special purpose computer, which is configured as a combination of a processor and a memory, which are programmed to perform one or more functions, and a processor which is configured with one or more hardware logic circuits. The computer programs may be stored, as instructions to be executed by a computer, in a tangible non-transitory computer-readable medium.

What is claimed is:

1. A method for manufacturing a silicon carbide semiconductor device, the method comprising:
preparing an n-type silicon carbide doped with an n-type impurity, which is to be used for forming an n-type silicon carbide substrate;
measuring an emission spectrum intensity due to a level formed in a vicinity of a mid-gap of silicon carbide by a p-type impurity mixed in the n-type silicon carbide by means of an emission spectrum measurement based on excitation; and
performing a quality determination to determine whether or not the n-type silicon carbide is a standard article by comparing the emission spectrum intensity with a reference value that is set based on an emission spectrum intensity corresponding to the mid-gap, wherein
in the measuring of the emission spectrum intensity, the emission spectrum measurement is performed based on the excitation that is caused by irradiating a photoluminescence light onto the n-type silicon carbide, and
the measuring of the emission spectrum intensity includes measuring an emission spectrum intensity corresponding to a p-type impurity concentration by measuring an emission spectrum intensity of a wavelength of 520 nm of the photoluminescence light.

2. The method according to claim 1, wherein
the p-type impurity includes one or more selected from a group consisting of B, Al, Ti, and V.

3. The method according to claim 1, wherein
in the performing of the quality determination, an emission spectrum intensity ratio, which is obtained by normalizing the emission spectrum intensity with a peak intensity in a wavelength range of 380±5 nm of the emission spectrum intensity as a reference, is compared with the reference value.

4. The method according to claim 1, wherein
in the preparing of the n-type silicon carbide, a silicon carbide ingot obtained by crystal growth of an n-type silicon carbide single crystal is prepared as the n-type silicon carbide, and
in the measuring of the emission spectrum intensity, the emission spectrum intensity of the silicon carbide ingot is measured.

5. The method according to claim 1, wherein
in the preparing of the n-type silicon carbide, a silicon carbide wafer sliced from a silicon carbide ingot produced by crystal growth of an n-type silicon carbide single crystal is prepared,
the measuring of the emission spectrum intensity includes at least one of:
measuring the emission spectrum intensity on a surface of the sliced silicon carbide wafer;
measuring the emission spectrum intensity on a surface of the sliced silicon carbide wafer, the surface having been polished by a lapping process; or
measuring the emission spectrum intensity on a surface of the silicon carbide wafer, the surface having been polished by a chemical mechanical polishing after the lapping process.

6. The method according to claim 1, wherein
the preparing of the n-type silicon carbide includes:
preparing an n-type silicon carbide wafer; and
forming an epitaxial film on one surface of the silicon carbide wafer, and
the measuring of the emission spectrum intensity is performed on another surface of the silicon carbide wafer, which is opposite to the one surface on which the epitaxial film is formed.

7. The method according to claim 1, wherein
the measuring of the emission spectrum intensity is performed at a temperature of 21 degrees Celsius or higher and 27 degrees Celsius or lower.
